(19) United States
(12) Patent Application Publication
(10) Pub. No.: US 2013/0008604 A1
(43) Pub. Date: Jan. 10, 2013

(54) METHOD AND APPARATUS FOR ENHANCING FLOW UNIFORMITY IN A PROCESS CHAMBER

(75) Inventors: KALLOL BERA, San Jose, CA (US); JAMES D. CARDUCCI, Sunnyvale, CA (US); AJIT BALAKRISHNA, Sunnyvale, CA (US); SHAHID RAUF, Pleasanton, CA (US); KENNETH S. COLLINS, San Jose, CA (US); ANDREW NGUYEN, San Jose, CA (US); HAMID NOORBAKHSH, Fremont, CA (US)

(73) Assignee: APPLIED MATERIALS, INC., Santa Clara, CA (US)

(21) Appl. No.: 13/613,941

(22) Filed: Sep. 13, 2012

Related U.S. Application Data
(63) Continuation of application No. 12/020,043, filed on Jan. 25, 2008.

(51) Int. Cl. H01L 21/306

(52) U.S. Cl. 156/345.29

(57) ABSTRACT

Methods and apparatus for processing substrates are provided herein. In some embodiments, an apparatus for processing a substrate may include a process chamber having an inner volume and an exhaust system coupled thereto, wherein the exhaust system includes a plurality of first conduits, each first conduit having an inlet adapted to receive exhaust from the inner volume of the process chamber. A pumping plenum is coupled to each of the plurality of first conduits. The pumping plenum has a pumping port adapted to pump the exhaust from the chamber. The conductance between each inlet of the plurality of first conduits and the pumping port is substantially equivalent.

### CROSS-REFERENCE TO RELATED APPLICATIONS

This application is a continuation of co-pending U.S. patent application Ser. No. 12/020,043, filed Jan. 25, 2008, which is herein incorporated by reference.

### FIELD

Embodiments of the present invention generally relate to semiconductor processing and, more particularly, to apparatus for processing substrates.

### BACKGROUND

As the critical dimensions for semiconductor devices continue to shrink, there is an increased need for semiconductor process equipment that can uniformly process semiconductor substrates. One instance of where this need may arise is in controlling the flow of process gases proximate the surface of a substrate disposed in a process chamber. The inventors have observed that, in conventional process chambers that utilize a single pump to exhaust process gases from a side of the process chamber, process non-uniformities (for example, non-uniform etch rates in an etch chamber) exits that are believed to be due, at least in part, to non-uniform flow of process gases in the process chamber.

Thus, there is a need in the art for an improved apparatus for processing substrates.

### SUMMARY

Methods and apparatus for processing substrates are provided herein. In some embodiments, an apparatus for processing a substrate may include a process chamber having an inner volume and an exhaust system coupled thereto, wherein the exhaust system includes a plurality of first conduits, each first conduit having an inlet adapted to receive exhaust from the inner volume of the process chamber. A pumping plenum is coupled to each of the plurality of first conduits. The pumping plenum has a pumping port adapted to pump the exhaust from the chamber. The conductance between each inlet of the plurality of first conduits and the pumping port is substantially equivalent.

In some embodiments, the exhaust system may further comprise a plurality of second conduits, wherein each second conduit couples at least two first conduits to the pumping plenum. In some embodiments, each second conduit couples two first conduits to the pumping plenum. Alternatively or in combination, in some embodiments, the flow length between each inlet and the pumping port may be substantially equivalent. In some embodiments, the cross sectional area along a flow length between the inlet and the pumping port may be substantially equivalent.

In some embodiments, an apparatus for processing a substrate may include a process chamber having an inner volume and an exhaust system coupled thereto. The exhaust system includes a plurality of first conduits and a plurality of second conduits. Each first conduit has an inlet adapted to receive exhaust from the inner volume of the process chamber. Each second conduit is coupled to a pair of first conduits. A pumping plenum is coupled to each of the plurality of second conduits. A pumping port is disposed in the pumping plenum and adapted to pump the exhaust from the chamber. A conductance between each inlet of the plurality of first conduits and the pumping port is substantially equivalent.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1 and 1A depict apparatus for processing semiconductor substrates in accordance with some embodiments of the present invention.

FIGS. 2A-B depict schematic, cross-sectional top views of several apparatus for processing semiconductor substrates in accordance with some embodiments of the present invention.

FIGS. 3A-B respectively depict illustrative graphs depicting etch rate uniformity across a substrate during processing in a semiconductor substrate processing chamber without and with an apparatus in accordance with embodiments of the invention.

FIG. 4 depicts a schematic, cross-sectional top view of an apparatus for processing semiconductor substrates in accordance with some embodiments of the present invention.

FIGS. 5A-C depict schematic, cross-sectional top view of apparatus for processing semiconductor substrates in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide an apparatus for processing a substrate (e.g., a process chamber) having an improved exhaust system for the removal of process gases. The improved exhaust system facilitates providing more uniform flow of gases proximate the surface of a substrate disposed within the apparatus. Such uniform flow of gases proximate the surface of the substrate may facilitate more uniform processing of the substrate.

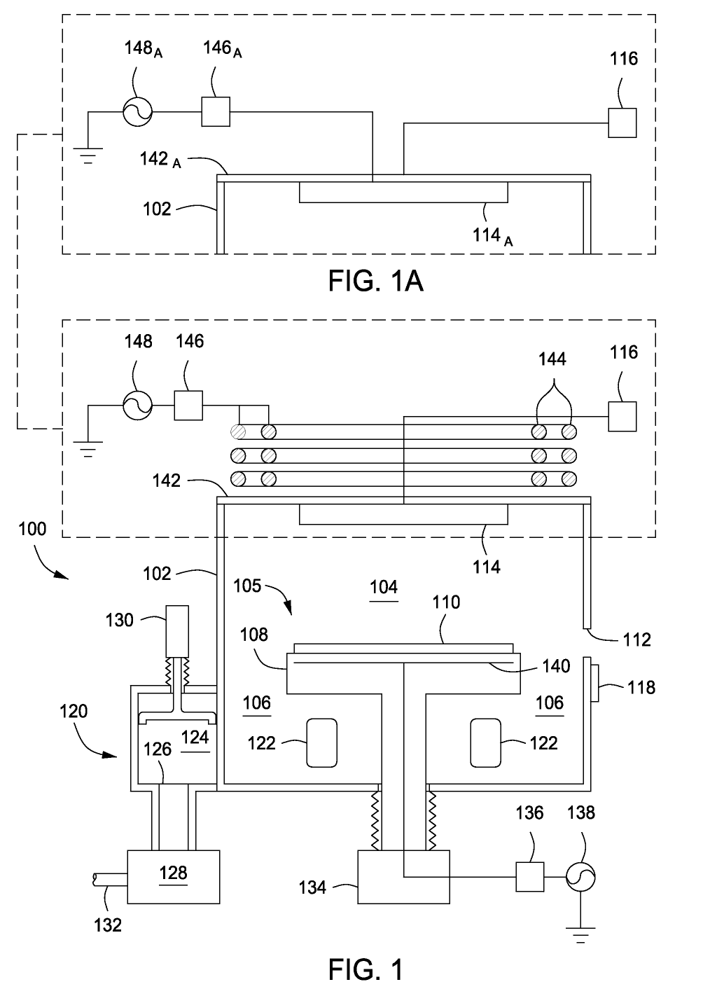

FIG. 1 depicts an apparatus 100 in accordance with some embodiments of the present invention. The apparatus 100 may comprise a process chamber 102 having an exhaust system 120 for removing excess process gases, processing by-products, or the like, from the interior of the process chamber 102. Exemplary process chambers may include the DPS®, ENABLER®, SIGMA™, ADVANTEDGE™, or other process chambers, available from Applied Materials, Inc. of Santa Clara, Calif. It is contemplated that other suitable chambers include any chambers that may require substantially uniform pressure, flow, and/or residence time of process gases flowing therethrough.

The process chamber 102 has an inner volume 105 that may include a processing volume 104 and an exhaust volume 106. The processing volume 104 may be defined, for example, between a substrate support pedestal 108 disposed within the process chamber 102 for supporting a substrate 110 thereupon during processing and one or more gas inlets, such as a showerhead 114 and/or nozzles provided at desired locations. In some embodiments, the substrate support pedestal 108 may include a mechanism that retains or supports the substrate 110 on the surface of the substrate support pedestal 108, such as an electrostatic chuck, a vacuum chuck, a substrate retaining clamp, or the like (not shown). In some embodiments, the substrate support pedestal 108 may include mechanisms for controlling the substrate temperature (such as heating and/or cooling devices, not shown) and/or for controlling the species flux and/or ion energy proximate the substrate surface.

For example, in some embodiments, the substrate support pedestal 108 may include an RF bias electrode 140. The RF bias electrode 140 may be coupled to one or more bias power sources (one bias power source 138 shown) through one or more respective matching networks (matching network 136 shown). The one or more bias power sources may be capable of producing up to 12000 W at a frequency of about 2 MHz, or about 13.56 MHz, or about 60 MHz. In some embodiments, two bias power sources may be provided for coupling RF power through respective matching networks to the RF bias electrode 140 at a frequency of about 2 MHz and about 13.56 MHz. In some embodiments, three bias power sources may be provided for coupling RF power through respective matching networks to the RF bias electrode 140 at a frequency of about 2 MHz, about 13.56 MHz, and about 60 MHz. The at least one bias power source may provide either continuous or pulsed power. In some embodiments, the bias power source may be a DC or pulsed DC source.

The substrate 110 may enter the process chamber 102 via an opening 112 in a wall of the process chamber 102. The opening 112 may be selectively sealed via a slit valve 118, or other mechanism for selectively providing access to the interior of the chamber through the opening 112. The substrate support pedestal 108 may be coupled to a lift mechanism 134 that may control the position of the substrate support pedestal 108 between a lower position (as shown) suitable for transferring substrates into and out of the chamber via the opening 112 and a selectable upper position suitable for processing. The process position may be selected to maximize process uniformity for a particular process step. When in at least one of the elevated processing positions, the substrate support pedestal 108 may be disposed above the opening 112 to provide a symmetrical processing region.

The one or more gas inlets (e.g., the showerhead 114) may be coupled to a gas supply 116 for providing one or more process gases into the processing volume 104 of the process chamber 102. Although a showerhead 114 is shown in FIG. 1, additional or alternative gas inlets may be provided such as nozzles or inlets disposed in the ceiling or on the sidewalls of the process chamber 102 or at other locations suitable for providing gases as desired to the process chamber 102, such as the base of the process chamber, the periphery of the substrate support pedestal, or the like.

In some embodiments, the apparatus 100 may utilize inductively coupled RF power for processing. For example, the process chamber 102 may have a ceiling 142 made from a dielectric material and a dielectric showerhead 114. The ceiling 142 may be substantially flat, although other types of ceilings, such as dome-shaped ceilings or the like, may also be utilized. An antenna comprising at least one inductive coil element 144 is disposed above the ceiling 142 (two co-axial elements 144 are shown). The inductive coil elements 144 are coupled to one or more RF power sources (one RF power source 148 shown) through one or more respective matching networks (matching network 146 shown). The one or more plasma sources may be capable of producing up to 5000 W at a frequency of about 2 MHz and/or about 13.56 MHz, or higher frequency, such as 27 MHz and/or 60 MHz. In some embodiments, two RF power sources may be coupled to the inductive coil elements 144 through respective matching networks for providing RF power at frequencies of about 2 MHz and about 13.56 MHz.

In some embodiments, and as shown in FIG. 1A, the apparatus 100 may utilize capacitively coupled RF power provided to an upper electrode proximate an upper portion of the process chamber 102. For example, the upper electrode may be a conductor formed, at least in part, by one or more of a ceiling 142_{A}, a showerhead 114_{A}, or the like, fabricated from a suitable conductive material. One or more RF power sources (one RF power source 148_{A} shown in FIG. 1A) may be coupled through one or more respective matching networks (matching network 146_{A} shown in FIG. 1A) to the upper electrode. The one or more plasma sources may be capable of producing up to 5000 W at a frequency of about 60 MHz and/or about 162 MHz. In some embodiments, two RF power sources may be coupled to the upper electrode through respective matching networks for providing RF power at frequencies of about 60 MHz and about 162 MHz. In some embodiments, two RF power sources may be coupled to the upper electrode through respective matching networks for providing RF power at frequencies of about 40 MHz and about 100 MHz.

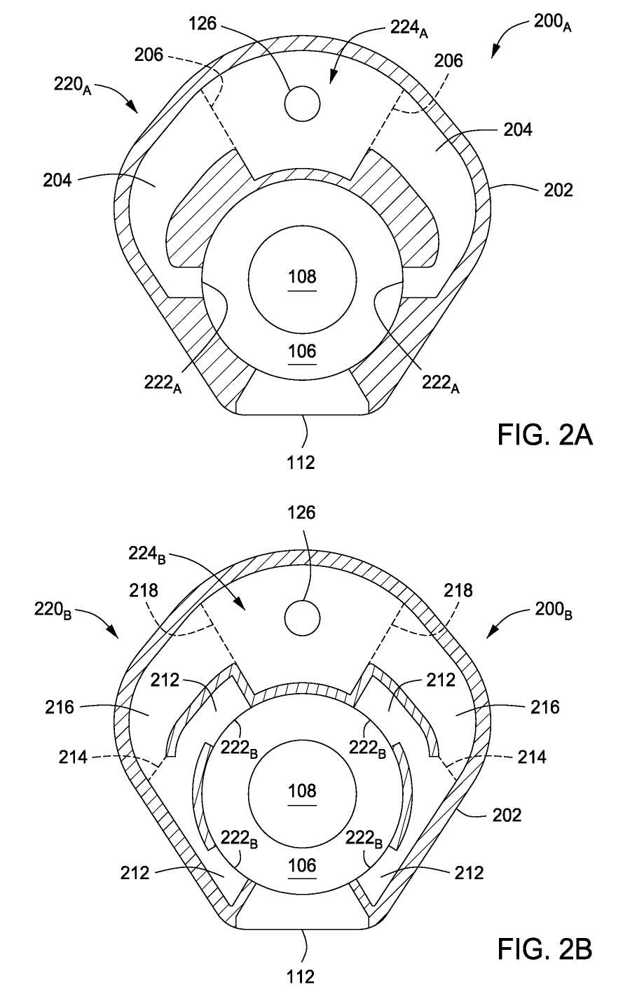

Returning to FIG. 1, the exhaust volume 106 may be defined, for example, between the substrate support pedestal 108 and a bottom of the process chamber 102. The exhaust volume 106 may be fluidly coupled to the exhaust system 120, or may be considered a part of the exhaust system 120. The exhaust system 120 generally includes a pumping plenum 124 and a plurality of conduits (described in more detail below in FIGS. 2A-B) that couple the pumping plenum 124 to the inner volume 105 (and generally, the exhaust volume 104) of the process chamber 102.

Each conduit has an inlet 122 coupled to the inner volume 105 (or, in some embodiments, the exhaust volume 106) and an outlet (not shown) fluidly coupled to the pumping plenum 124. For example, each conduit may have an inlet 122 disposed in a lower region of a sidewall or a floor of the process chamber 102. In some embodiments, the inlets are substantially equidistantly spaced from each other.

A vacuum pump 128 may be coupled to the pumping plenum 124 via a pumping port 126 for pumping out the exhaust gases from the process chamber 102. The vacuum pump 128 may be fluidly coupled to an exhaust outlet 132 for routing the exhaust as required to appropriate exhaust handling equipment. A valve 130 (such as a gate valve, or the like) may be disposed in the pumping plenum 124 to facilitate control of the flow rate of the exhaust gases in combination with the operation of the vacuum pump 128. Although a z-motion gate valve is shown, any suitable, process compatible valve for controlling the flow of the exhaust may be utilized.

The exhaust system 120 facilitates uniform flow of the exhaust gases from the inner volume 105 of the process chamber 102. For example, the exhaust system 120 may provide at least one of reduced variance of flow resistance azimuthally (or symmetrically) about the substrate support pedestal 108 (e.g., substantially equal flow resistance), or substantially equal residence time for the exhaust flow to the pump. Accordingly, in some embodiments, the plurality of conduits may have a substantially equal conductance. As used herein, the term substantially equivalent, or substantially equal, means within about 10 percent of each other). The terms substantially equivalent or substantially equal, as defined above, may be used to describe other aspects of the invention, such as conduit length, flow length, cross-sectional area, or the like, as described in more detail below. In some embodiments, the plurality of conduits may have a high conductance, or a high conductance as compared to the pump speed. The conductance may be controlled by the combination of the conductivity of the medium through which the exhaust gases may be exhausted (e.g., such as atmospheric or vacuum conditions), the flow length of the conduit (e.g., a distance of the mean flow path between each inlet and the pumping port), and the cross-sectional area of the conduit along the flow length.

In some embodiments, the plurality of conduits may have a substantially equal flow length. In some embodiments, the plurality of conduits may have a substantially equal cross-sectional area along an equivalent position therealong (e.g., the cross-sectional area may vary along the length of each conduit, but each conduit in the plurality will vary in a substantially equivalent manner). In some embodiments, the plurality of conduits may be symmetrically arranged about the process chamber. In some embodiments, the plurality of conduits may be symmetrically arranged about a vertical plane passing through pumping port 126 and the substrate support pedestal 108 of the process chamber 102.

The exhaust system of the present invention may be provided in a variety of embodiments. For example, FIGS. 2A-B respectively depict schematic, cross-sectional top views of an apparatus 200_{A} and 200_{B} in accordance with embodiments of the present invention. With the exception of the details described below with respect to FIGS. 2A-B, the apparatus 200_{A} and 200_{B} may otherwise be similar to the apparatus 100 described above.

In some embodiments, and as shown in FIG. 2A, the apparatus 200_{A} may include a process chamber 202 having an inner volume (exhaust volume 106 shown) and a substrate support pedestal 108 disposed therein. An exhaust system 220_{A} may be provided having a plurality of first conduits 204 and a pumping plenum 224_{A}. Each first conduit 204 has an inlet 222_{A} for receiving exhaust from the inner volume of the process chamber 202 and an outlet 206 coupled to the pumping plenum 224_{A}. The inlets 222_{A} may be substantially equidistantly spaced about the substrate support pedestal 108. A pumping port 126 may be disposed in the pumping plenum 224_{A} for pumping the exhaust gases from the chamber 202 as discussed above.

In some embodiments, the conductance in each flow path through the exhaust system 220_{A} from the inner volume of the process chamber 202 to the pumping port 126 is substantially equal. For example, in some embodiments, each of the plurality of first conduits 204 may have a substantially equal conductance. In some embodiments, the conductance between each inlet 222_{A} of the plurality of first conduits 204 and the pumping port 126 may be within about 10 percent of each other.

In some embodiments, the flow length of exhaust gases as defined by the mean flow path between each inlet 222_{A} and the pumping port 126 may be substantially equivalent. Alternatively or in combination, in some embodiments, a cross-sectional area along the flow length may be substantially equivalent at an equivalent position therealong.

In some embodiments, an axial length of each first conduit 204 may be substantially equivalent. The axial length may be defined as the length along a central longitudinal axis of the conduit. Alternatively or in combination, in some embodiments, the cross sectional area along the axial length may be substantially equivalent at an equivalent position therealong.

In some embodiments, and as depicted in FIG. 2B, the apparatus 200_{B} may include a process chamber 202 having an inner volume (exhaust volume 106 shown) and a substrate support 108 disposed therein. An exhaust system 220_{B} may be provided having a plurality of first conduits 212, a plurality of second conduits 216, and a pumping plenum 224_{B}. Each first conduit 212 includes an inlet 222_{B} for receiving exhaust from the inner volume (or exhaust volume 106) of the process chamber 202 and an outlet. Multiples of at least two of the plurality of first conduits 212 each share a common outlet 214, which also corresponds to an inlet of one of the plurality of second conduits 216. Thus, each of the plurality of second conduits 216 is coupled to at least two of the plurality of first conduits 212. In some embodiments, each second conduit 216 is coupled to two first conduits 212. Each second conduit 216 further includes an outlet 218 coupled to the pumping plenum 224_{B}. A pumping port 126 may be disposed in the pumping plenum 224_{B} for pumping the exhaust gases from the chamber 202 as discussed above.

In some embodiments, the conductance in each flow path through the exhaust system 220_{B} from the inner volume of the process chamber 202 to the pumping port 126 is substantially equal. For example, in some embodiments, the conductance between each inlet 222_{B} of the plurality of first conduits 212 and the pumping port 126 is substantially equivalent. In some embodiments, the conductance between each inlet 222_{B} of the plurality of first conduits 212 and the pumping port 126 may be within about 10 percent of each other.

In some embodiments, a flow length between each inlet 222_{B} and the pumping port 126 may be substantially equivalent. Alternatively or in combination, in some embodiments, a cross sectional area along the flow length between each inlet 222_{B} and the pumping port 126 may be substantially equivalent at an equivalent position therealong.

In some embodiments, an axial length of each first conduit 212 may be substantially equivalent, and an axial length of each second conduit 216 may be substantially equivalent. Alternatively or in combination, in some embodiments, a cross sectional area of each first conduit 212 along the axial length may be substantially equivalent at an equivalent position therealong, and a cross sectional area of each second conduit 216 along the axial length may be substantially equivalent at an equivalent position therealong.

As depicted in FIGS. 2A-B, the exhaust system may be symmetrically arranged with respect to the process chamber. Specifically, the exhaust system may be symmetrically arranged with respect to a vertical plane including a line passing through the substrate support pedestal and the pumping port. In some embodiments, such a vertical plane or line may also include a central axis of a slit valve opening (such as opening 112 depicted in FIG. 1). This symmetry is an example of one arrangement only, and other symmetric arrangements of the exhaust system are contemplated. Although the exemplary exhaust system described above contains a symmetrical arrangement, an asymmetric arrangement may be utilized as well.

Although FIG. 2B depicts a single iteration of recursive levels of conduits (e.g., plurality of first conduits coupled to plurality of second conduits), additional iterations of the recursive design are contemplated. For example, a plurality of third conduits may be provided, each third conduit coupled to at least two second conduits. More generally, a recursive system of n levels of conduits may be provided, each conduit in a level closer to the pump port coupled to at least two conduits of an adjacent level moving towards the inner volume of the chamber.

Thus, the exhaust system generally includes a plurality of flow paths from the inner volume of the process chamber to the pumping port, each flow path having a substantially equal conductance. The flow paths may systematically aggregate as they move from near the inner volume to near the pumping port, or viewed from the other direction, each flow path from the pumping port may split into two or more sub-flow paths in a direction from near the pumping port to near the inner volume of the chamber. Each split generally occurs at a common point along each flow path (e.g., to retain substantially equal conductance through each of the flow paths). The similar conductance between flow paths facilitates similar flow resistance and/or equal residence time for the exhaust to reach the pump, thereby improving process characteristics such as pressure and/or velocity profiles above the substrate during processing.

For example, referring to FIG. 1 and FIGS. 2A-B, in operation, a substrate (such as substrate 110) may be disposed on the substrate support pedestal 108 and one or more process gases may be introduced into the processing volume 104 via the showerhead 114 (and/or other gas inlets). The substrate 110 may then be processed by the process gases, which may be in a plasma or non-plasma state, such as by etching the substrate, depositing a layer of material on the substrate, treating the substrate, or otherwise processing the substrate as desired. As the process gases are utilized to process the substrate, undesirable constituents (e.g., exhaust gases) in the processing volume 104 (such as excess unreacted process gases, process gas constituents or components, processing by-products, decomposed or broken down process gases or processing by-products, or the like) may be exhausted from the chamber 102 through the exhaust system 120. Although referred to herein as exhaust gases, it is contemplated that liquid or solid matter may also be entrained within the exhaust gases and are included within the scope of the term exhaust gases.

Without the use of the inventive apparatus disclosed herein, the location of the showerhead, substrate support pedestal, and exhaust port of conventional process chambers causes an uneven distribution of pressure and velocity across the surface of the substrate as the gases flow into and out of the process chamber. It is believed that this uneven pressure and velocity distribution affects the distribution of process gases in the chamber (for example, the location of a plasma or the uniformity of gaseous compositions in the chamber) and, therefore, the uniformity of the process being performed (for example, etch rate uniformity, deposition uniformity, or the like).

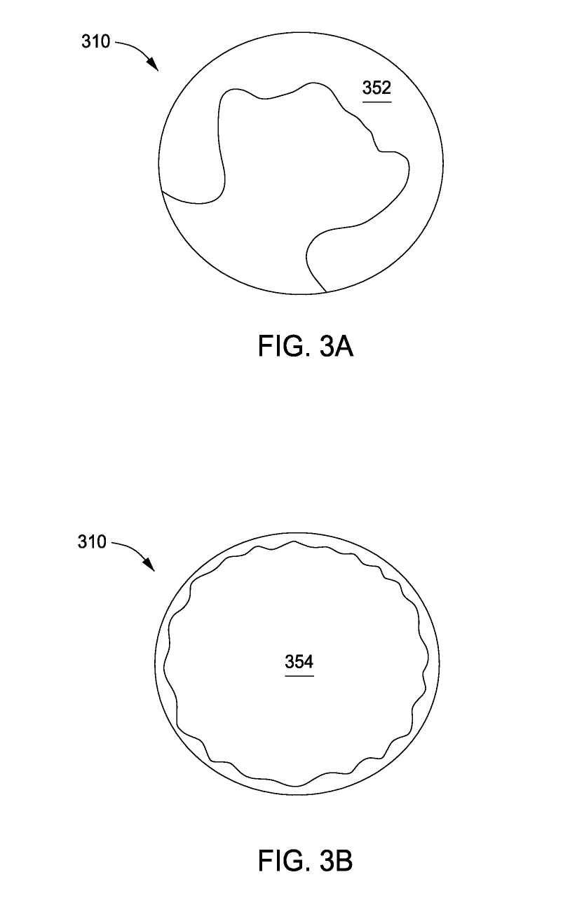

For example, FIGS. 3A-B are graphic representations of measurements taken which show the etch rate uniformity across the surface of a substrate with and without the use of an apparatus as described herein in accordance with embodiments of the invention. FIG. 3A shows an area of greater etch rate 352 on the surface of a substrate 310 in a conventional side-pumping process chamber. As can be seen from the figure, the reactive species has moved to one side of the substrate 310 due to the non-uniform gas flow within the chamber. This offset in location of the reactive species causes non-uniformity in the etch rate of the substrate 310, as indicated by the area of greater etch rate 352. FIG. 3B shows the improved area of greater etch rate 354 on the surface of a substrate 310 with the use of an apparatus as described herein in accordance with embodiments of the present invention. As can be seen in this figure, the reactive species is centered over the surface of the substrate 310 and results in a much more uniform area of greater etch rate 354.

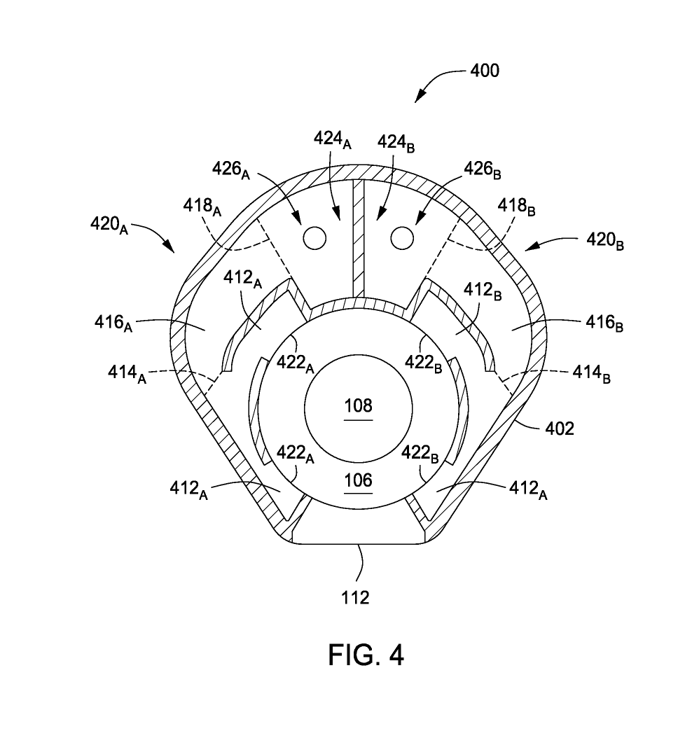

In some embodiments, a process chamber may include more than one exhaust system. For example, FIG. 4 illustratively depicts an apparatus 400 having two exhaust systems (or one exhaust system that includes two pumps independently coupled to the inner volume of the process chamber). As shown in FIG. 4, the apparatus 400 may include a process chamber 402 having an inner volume (exhaust volume 106 shown) and a substrate support pedestal 108 disposed therein. A first exhaust system 420_{A} and a second exhaust system 420_{B} may be coupled to the inner volume of the process chamber 402. The first and second exhaust systems 420_{A-B} may be configured using the principles described above relating to conductance, recursiveness, symmetry, and the like. For example, the first exhaust system 420_{A} may be provided having a plurality of first conduits 412_{A}, at least one second conduit 416_{A}, and a first pumping plenum 424_{A}. Each first conduit 412_{A} includes an inlet 422_{A} for receiving exhaust from the inner volume (or exhaust volume 106) of the process chamber 402 and an outlet. At least two of the plurality of first conduits 412_{A} each share a common outlet 414_{A} that corresponds to an inlet of one second conduit 416_{A}. Thus, each second conduit 416_{A} is coupled to at least two of the plurality of first conduits 412_{A}. In some embodiments, each second conduit 416_{A} is coupled to two first conduits 412_{A}. Each second conduit 416_{A} further includes an outlet 418_{A} coupled to the first pumping plenum 424_{A}. A first pumping port 426_{A} may be disposed in the first pumping plenum 424_{A} for pumping the exhaust gases from the chamber 402, as discussed above.

In some embodiments, the conductance in each flow path through the first exhaust system 420_{A} from the inner volume of the process chamber 402 to the first pumping port 426_{A} is substantially equal. For example, in some embodiments, the conductance between each inlet 422_{A} of the plurality of first conduits 412_{A} and the first pumping port 426_{A} is substantially equivalent. In some embodiments, the conductance between each inlet 422_{A} of the plurality of first conduits 412_{A} and the first pumping port 426_{A} may be within about 10 percent of each other.

In some embodiments, the flow length of exhaust gases as defined by the mean flow path between each inlet 422_{A} and the pumping port 426_{A} may be substantially equivalent. Alternatively or in combination, in some embodiments, a cross-sectional area along the flow length may be substantially equivalent at an equivalent position therealong. In some embodiments, an axial length of each first conduit 412_{A} may be substantially equivalent. Alternatively or in combination, in some embodiments, the cross sectional area along the axial length may be substantially equivalent at an equivalent position therealong.

A second exhaust system 420_{B} may be provided having a second plurality of first conduits 412_{B}, at least one second conduit 416_{B} (or a second plurality of second conduits), and a second pumping plenum 424_{B}. Each first conduit 412_{B} includes an inlet 422_{B} for receiving exhaust from the inner volume (or exhaust volume 106) of the process chamber 402 and an outlet. At least two of the second plurality of first conduits 412_{B} each share a common outlet 414_{B} that corresponds to an inlet of one second conduit 416_{B}. Thus, each second conduit 416_{B} is coupled to at least two of the second plurality of first conduits 412_{B}. In some embodiments, each second conduit 416_{B} is coupled to two first conduits 412_{B}. Each second conduit 416_{B} further includes an outlet 418_{B} coupled to the second pumping plenum 424_{B}. A second pumping port 426_{B} may be disposed in the second pumping plenum 424_{B} for pumping the exhaust gases from the chamber 402 as discussed above. Each pumping port 426_{A-B} may be coupled to a separate pump (e.g., similar to pump 128 shown in FIG. 1).

The second exhaust system 420_{B} may be varied in similar manner as described above with respect to the first exhaust system 420_{A}. For example, the relationship between at least one of the conductance in each flow path through the second exhaust system 420_{B}, the conductance between the between each inlet 422_{B} of the second plurality of first conduits 412_{B} and the second pumping port 426_{B}, the flow length of exhaust gases, a cross-sectional area along the flow length, an axial length of each first conduit 412_{B}, or the cross sectional area along the axial length, may be varied as described above with respect to the first exhaust system 420_{A}.

In some embodiments, the first exhaust system 420_{A} and the second exhaust system 420_{B} may be identical. Alternatively, the first and second exhaust systems, 420_{A} and 420_{B}, may be substantially equivalent to each other. It is contemplated that the first and second exhaust systems, 420_{A} and 420_{B}, may have other configurations in keeping with the principles disclosed herein. For example, the first and second exhaust systems, 420_{A} and 420_{B}, may be configured similar to the exhaust system 220_{A} as described in above with respect to FIG. 2A, or with different levels of recursiveness or numbers of conduits in any of the recursive levels of exhaust conduits.

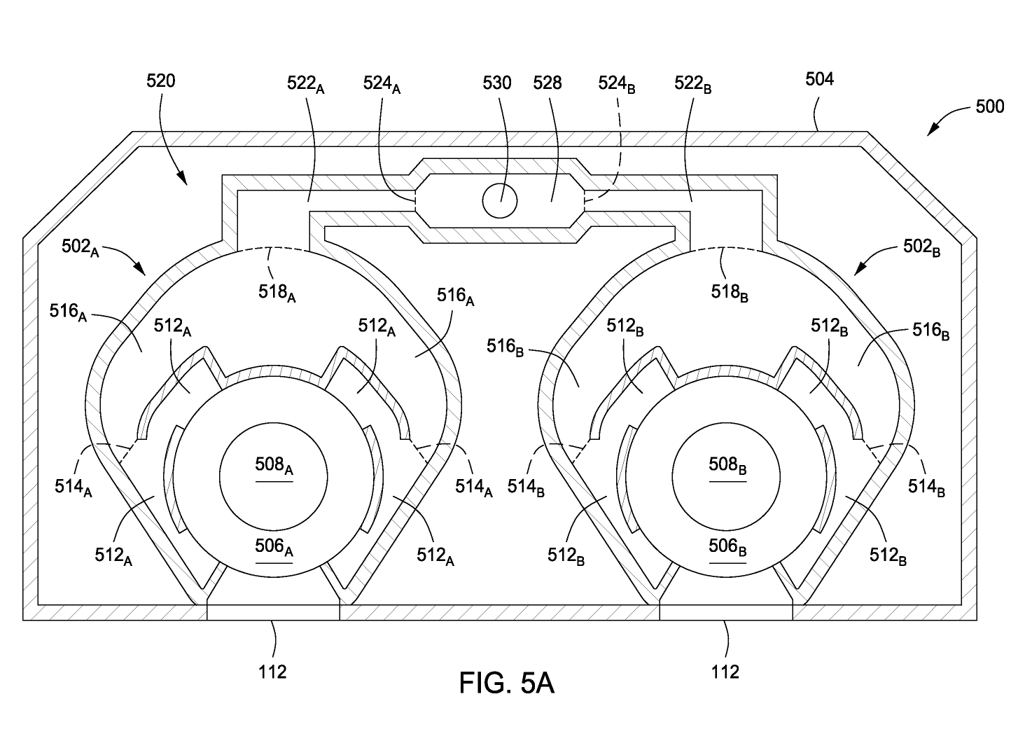

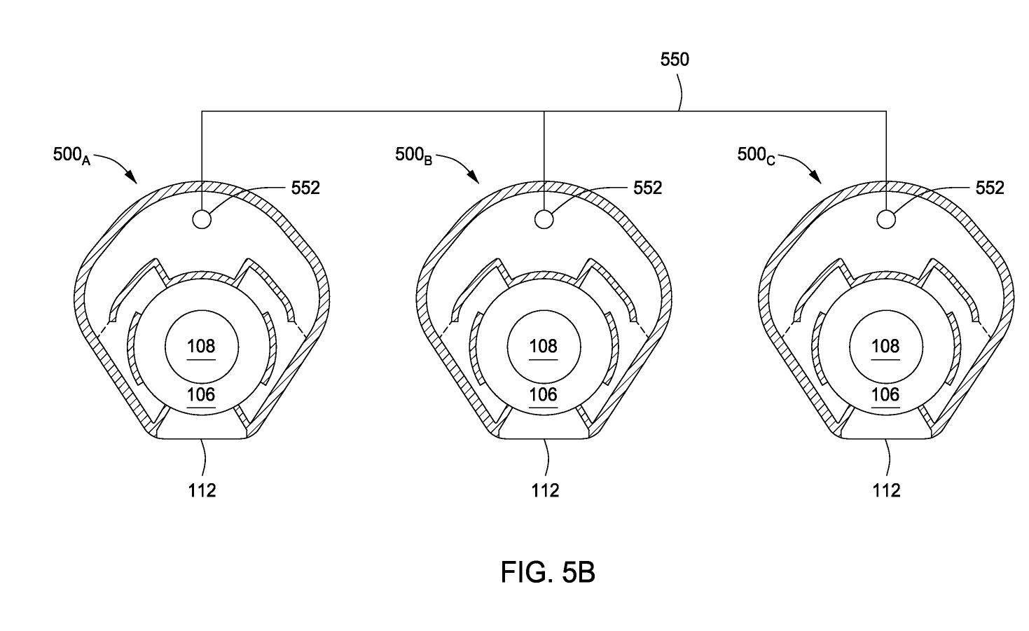

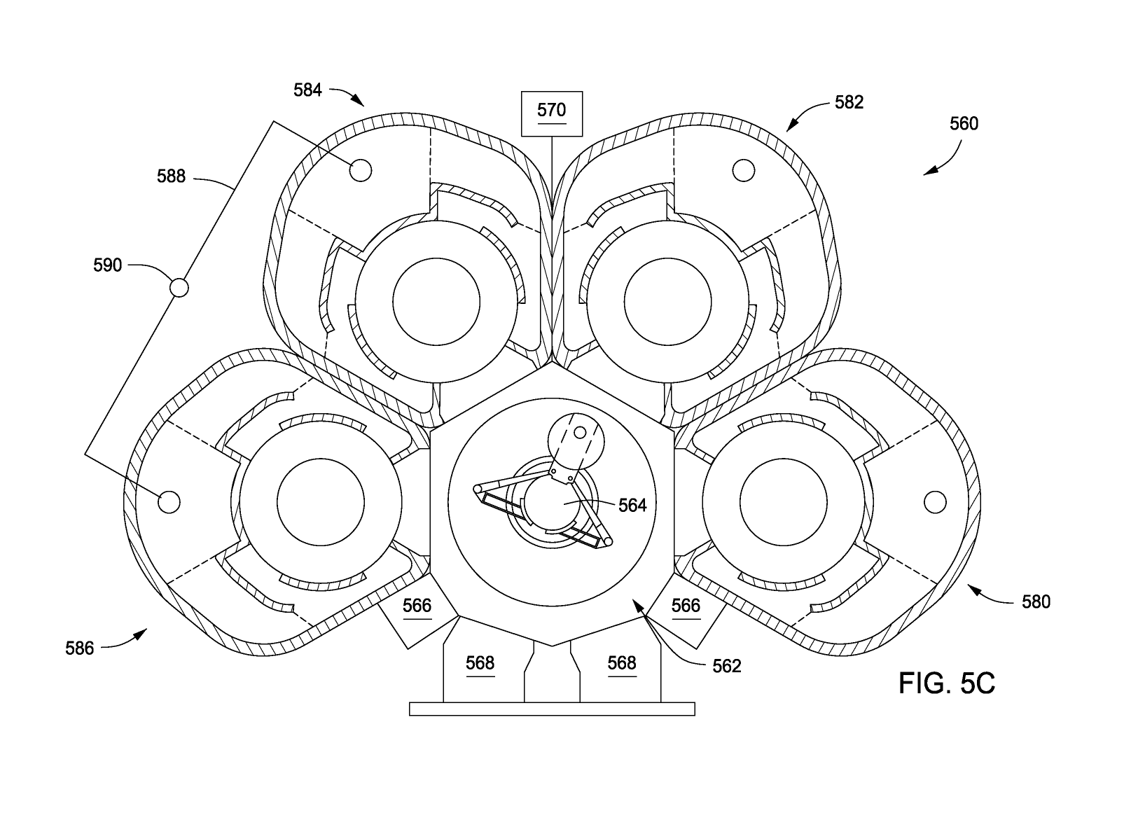

In some embodiments, an apparatus may include more than one process chamber coupled to the exhaust system (e.g., each chamber having an exhaust system that may share a common pumping plenum, pumping port, and pump). Non-limiting examples of such apparatus are depicted in FIGS. 5A-C.

FIG. 5A depicts a semiconductor processing apparatus 500 which may comprise more than one process chamber for processing a semiconductor substrate (two chambers 502_{A} and 502_{B} shown). Each process chamber may have an exhaust system that is coupled to a common pumping plenum 528 and pumping port 530. In some embodiments, the exhaust systems in each process chamber may be identical or substantially equivalent. One such exemplary apparatus that may be suitably modified in accordance with the teachings provided herein is the PRODUCER® chamber, available from Applied Materials, Inc. of Santa Clara, Calif.

The apparatus 500 includes at least two process chambers 502_{A-B} disposed within a common housing 504. Each process chamber 502_{A-B} may be configured as described in any of the embodiments discussed above (or variants thereof). For illustrative purposes, each process chamber 502_{A-B} is shown in FIG. 5A is configured similar to the apparatus 200_{B} described with respect to FIG. 2B except as described below. Each process chamber 502_{A-B} includes an inlet 112 disposed therein and through the housing 504 for transferring semiconductor substrates therethrough. Each process chamber 502_{A-B} further includes an inner volume (exhaust volumes 506_{A-B} shown) and a substrate support pedestal 508_{A-B} disposed therein. An exhaust system 520 is respectively coupled to each process chamber 502_{A} and 502_{B}. Viewed alternatively, the exhaust systems 520 may be seen as two exhaust systems coupled to each of the process chambers 502_{A-B} and sharing a common pumping plenum and pumping port. The configuration of the exhaust system 520 in each process chamber 502_{A} or 502_{B} may be the same, different, or substantially equivalent.

For example, the exhaust system 520 may include a plurality of first conduits (e.g., 512_{A}, 512_{B}) coupled to each chamber 502_{A}, 502_{B}, each having an inlet (e.g., 522_{A}, 522_{B}) coupled to the respective inner volume of the chamber (e.g., 506_{A}, 506_{B}). The inlets fluidly couple the inner volumes of the respective chambers to the exhaust pump (not shown) via the pump port 530. In some embodiments, the conductance of each flow path from a respective inlet (e.g., 522_{A}, 522_{B}) to the pump port 530 may be substantially equivalent.

As discussed above, the exhaust system may include a plurality of recursive levels of aggregation of the exhaust conduits. Accordingly, in some embodiments, and as depicted in FIG. 5A, a plurality of second conduits may be provided (e.g., 516_{A}, and 516_{B}), each second conduit coupled to at least two first conduits between the first conduits and the pump port 530. For example, multiples of at least two of the plurality of first conduits 512_{A} may each share a common outlet (e.g., 514_{A}, 514_{B}) that corresponds to an inlet of one of the plurality of second conduits. Thus, each of the plurality of second conduits is coupled to at least two of the plurality of first conduits.

In some embodiments, a plurality of third conduits (e.g., 522_{A}, 522_{B}) may be provided, each third conduit coupled to at least two second conduits between the second conduits and the pump port 530. For example, multiples of at least two of the plurality of second conduits may each share a common outlet (e.g., 518_{A}, 518_{B}) that corresponds to an inlet of one of the third conduits. Thus, each third conduit is coupled to at least two of the plurality of second conduits. Each third conduit may include an outlet (e.g., 524_{A}, 524_{B}) coupled to the pumping plenum 528. The pumping port 530 is disposed in the pumping plenum 528 for pumping the exhaust gases from the chambers as discussed above. In some embodiments, the plurality of third conduits may be replaced by, or considered as, a single pumping plenum having the pump port 530 disposed therein.

As discussed above, in some embodiments, the conductance in each flow path through the exhaust system 520 from the inner volumes of the respective process chambers to the pumping port 530 may be substantially equal. For example, in some embodiments, the conductance between each inlet of the plurality of first conduits and the pumping port 530 may be substantially equivalent (e.g., within about 10 percent of each other). In some embodiments, the conductance within any of the levels of recursive aggregation of the exhaust system may be substantially equivalent (e.g., within the plurality of first conduits, within the plurality of second conduits, and the like). Other variables and configurations as discussed above (such as axial flow length, cross-sectional area, and the like) also are contemplated.

In some embodiments, multiple independent or standalone process chambers may each have an exhaust system that share a common pumping plenum and pumping port. For example, as schematically illustrated in FIG. 5B, three process chambers 500_{A}, 500_{B}, and 500_{C} have exhaust systems sharing a common a pumping plenum 550 having a pump port (not shown) disposed therein. The properties of each exhaust system, such as conductance, axial flow lengths, cross-sectional areas, and the like, may be configured similar to the exhaust systems described above. However, instead of having a pumping plenum and pump port coupled to a pump in each chamber, each chamber may have an outlet 552 (which may be similar to the pump port 126 described above, or may be an outlet of a conduit or aggregation of conduits of each respective chamber) that is coupled to a pump via a pumping port in a pumping plenum 550. The pumping plenum 550 (or recursive levels of conduits coupled thereto, similar as described above) couples each of the respective process chambers to a single pump utilizing the principles described above (e.g., substantially equivalent conductance, flow rates, axial flow paths, cross-sectional areas of conduits, and/or the like).

In some embodiments, the apparatus described above may be part of a cluster tool. In some embodiments, a cluster tool may include one or more of the process chamber embodiments described above. Exemplary cluster tools which may be adapted for the present invention include any of the CENTURA® line of cluster tools, available from Applied Materials, Inc., of Santa Clara, Calif.

By way of illustration, a particular cluster tool 560 is schematically shown in plan view in FIG. 5C. The cluster tool 560 generally comprises a plurality of process chambers (e.g., process chambers 580, 582, 584, 586) coupled to a central transfer chamber 562 housing a robot 564 therein for transferring substrates between the various chambers coupled to the central transfer chamber 562. Exemplary process chambers coupled to the central transfer chamber 562 may include any of the chambers described hereinabove. Any of the process chambers 580, 582, 584, 586 may be independently configured with an exhaust system similar to those discussed above. In addition, any two or more of the process chambers 580, 582, 584, 586 may be coupled to a singular exhaust system, similar to as discussed above with respect to FIGS. 5A and 5B. For example, as illustratively depicted in FIG. 5C, process chambers 584 and 586 may be coupled to a common pumping plenum 588 having a pump port 590 disposed therein. It is contemplated that other cluster tools having other configurations and numbers of process chambers coupled thereto may also benefit from modification of their exhaust systems in accordance with the principles disclosed herein.

Additional chambers, such as service chambers 566 adapted for degassing, orientation, cooldown, or the like, may also be coupled to the central transfer chamber 562. One or more load lock chambers 568 (two shown) may further be provided to couple the central transfer chamber 562 to a front-end environment (not shown). The cluster tool 560 may be equipped with a controller 570 programmed to carry out the various processing methods performed in the cluster tool 560.

Thus, methods and apparatus for processing substrates have been provided herein that provide improved uniformity of gas flow proximate the surface of a substrate. The improved uniformity of gas flow facilitates improvement of substrate processing, such as etching, deposition, or other processes that may benefit from uniformity of gas flow.

While the foregoing is directed to embodiments of the present invention, other and further embodiments of the invention may be devised without departing from the basic scope thereof.

What is claimed is:

1. An apparatus for processing a substrate, comprising:
a process chamber having an inner volume; and
an exhaust system coupled to the process chamber, the exhaust system comprising:
a plurality of first conduits, each first conduit having an inlet adapted to receive exhaust from the inner volume of the process chamber;
a pumping plenum having a pumping port adapted to pump the exhaust from the process chamber, wherein the conductance over the entire length between each inlet of the plurality of first conduits and the pumping port is substantially equivalent; and
a plurality of second conduits, wherein the plurality of second conduits couple the plurality of first conduits to the pumping plenum.

2. The apparatus of claim 1, wherein each second conduit couples at least two first conduits to the pumping plenum.

3. The apparatus of claim 1, wherein the exhaust system is symmetrically arranged with respect to a vertical plane including a line passing through a center of the substrate support pedestal and a center of the pumping plenum.

4. The apparatus of claim 1, wherein an axial length of each first conduit is substantially equivalent and wherein an axial length of each second conduit is substantially equivalent.

5. The apparatus of claim 1, wherein a cross sectional area of each first conduit is substantially equivalent at an equivalent position therealong and wherein a cross sectional area of each second conduit is substantially equivalent at an equivalent position therealong.

6. The apparatus of claim 1, wherein each second conduit is coupled to two first conduits.

7. The apparatus of claim 1, wherein a flow length between each inlet of the first plurality of conduits and the pumping plenum is substantially equivalent.

8. The apparatus of claim 1, wherein each of the plurality of first conduits includes at least two inlets.

9. The apparatus of claim 1, wherein the exhaust system provides a residence time for process gases flowing from each inlet of the plurality of first conduits to the pumping port that is substantially equivalent.

10. The apparatus of claim 1, further comprising:
a second exhaust system coupled to the process chamber, the second exhaust system comprising:
a second plurality of first conduits, each first conduit having an inlet adapted to receive exhaust from the inner volume of the process chamber; and
a second pumping plenum coupled to each of the second plurality of first conduits, the second pumping plenum having a second pumping port adapted to pump the exhaust from the process chamber, wherein the conductance between each inlet of the second plurality of first conduits and the second pumping port is substantially equivalent.

11. An apparatus for processing a substrate, comprising:
a process chamber having an inner volume; and
an exhaust system coupled to the process chamber, the exhaust system comprising:
a plurality of first conduits, each first conduit having an inlet adapted to receive exhaust from the inner volume of the process chamber;
a plurality of second conduits, each second conduit coupled to a pair of first conduits;
a pumping plenum coupled to each of the plurality of second conduits; and
a pumping port disposed in the pumping plenum and adapted to pump the exhaust from the chamber;
wherein a conductance over the entire length between each inlet of the plurality of first conduits and the pumping port is substantially equivalent.

12. The apparatus of claim 11, further comprising:
a substrate support pedestal disposed within the process chamber, wherein the inlets of the plurality of first conduits are substantially equidistantly spaced thereabout.

13. The apparatus of claim 11, wherein the exhaust system is symmetrically arranged with respect to a vertical plane including a line passing through a center of the substrate support pedestal and a center of the pumping plenum.

14. The apparatus of claim 11, wherein an axial length of each of the plurality of first conduits is substantially equivalent and wherein an axial length of each of the plurality of second conduits is substantially equivalent.

15. The apparatus of claim 11, wherein a cross sectional area of each of the plurality of first conduits is substantially equivalent at an equivalent position therealong and wherein a cross sectional area of each of the plurality of second conduits is substantially equivalent at an equivalent position therealong.

16. The apparatus of claim 11, wherein a flow length between each inlet of the first plurality of conduits and the pumping plenum is substantially equivalent.

17. The apparatus of claim 11, wherein a cross sectional area along the flow length between each inlet of the plurality of first conduits and the pumping plenum is substantially equivalent at an equivalent position therealong.

18. The apparatus of claim 11, further comprising:
a second exhaust system coupled to the process chamber, the second exhaust system comprising:
a second plurality of first conduits, each first conduit having an inlet adapted to receive exhaust from the inner volume of the process chamber;
a second plurality of second conduits, each second conduit coupled to at least two of the second plurality of first conduits;
a second pumping plenum coupled to each of the second plurality of second conduits; and
a second pumping port disposed in the second pumping plenum and adapted to pump the exhaust from the chamber, wherein a conductance over the entire length between each inlet of the second plurality of first conduits and the second pumping port is substantially equivalent.

19. The apparatus of claim 11, wherein each of the plurality of first conduits includes at least two inlets.

20. The apparatus of claim 11, wherein the exhaust system provides a residence time for process gases flowing from each inlet of the plurality of first conduits to the pumping port that is substantially equivalent.
